(19) United States
(12) Patent Application Publication
(10) Pub. No.: US 2025/0202144 A1
(43) Pub. Date: Jun. 19, 2025

(54) ELECTRONIC CONNECTORS FOR USE ON BOARD A SPACECRAFT

(71) Applicant: AIRBUS DEFENCE AND SPACE SAS, Toulouse Cedex 4 (FR)

(72) Inventors: Denis GALIANA, Toulouse Cedex 4 (FR); Lionel AUDIN, Toulouse Cedex 4 (FR); Clément COUTANCE, Toulouse Cedex 4 (FR); Théo MILLE-CHARNAY, Toulouse Cedex 4 (FR); Florent GUEDON, Toulouse Cedex 4 (FR)

(21) Appl. No.: 18/693,484

(22) PCT Filed: Sep. 21, 2022
(86) PCT No.: PCT/FR2022/051772

§ 371 Date: Feb. 10, 2025

(30) Foreign Application Priority Data
Sep. 23, 2021 (FR) 2110034

(51) Int. Cl. H01R 12/73; H01R 12/70; H01R 12/72; H05K 1/02; H05K 7/14; H05K 7/20

(52) U.S. Cl. CPC H01R 12/737; H01R 12/7047; H01R 12/727; H05K 1/0278; H05K 7/1434; H05K 7/20309; H05K 7/20381; H05K 2201/045; H05K 2201/10189

(57) ABSTRACT

An electronic device (1) suitable for use on board a spacecraft, including a motherboard (2) electrically connected to daughterboards (3a, 3b, 3c), the motherboard and the daughterboards each include a support plate (4a, 4b, 4c, 5) in order to form a printed circuit board, each support plate extending in a respective main plane, wherein each daughterboard includes a first electrical connector (6a, 6b, 6c, 6d) fixed to its support plate and the motherboard includes a corresponding number of second connectors (7a, 7b, 7c, 7d) fixed to the support plate of the motherboard, each first electrical connector engages with one of the second connectors, the first electrical connector of each daughterboard is arranged on a portion of the support plate forming a tab (8a, 8b, 8c, 8d) configured for deflection relative to the main plane of the printed circuit board.

### TECHNICAL FIELD

This disclosure relates to connectors used on board a spacecraft, the spacecraft being equipped with at least one motherboard and with daughterboards.

### PRIOR ART

In the field of space, each circuit board is held in its housing, which is fixed to a thermally regulated structure of the spacecraft. When interconnecting the circuit boards, an issue with board misalignment frequently arises, resulting from variations in the boards' dimensional tolerances, the location of the connectors, or the flatness of the circuit boards.

It is possible to mount printed circuit boards or PCBs on rails, but these reduce the heat exchange surface areas and therefore the maximum heat flux that can be achieved in a spatial environment. The mass of the rails is also a disadvantage of this solution.

Alternatively, it is possible for example to use boards formed from a flexible PCB, also called “flex PCB”, meaning a printed circuit board comprising a flexible substrate, for example formed of a polyimide or PEEK film, on which the electrically conductive tracks are arranged.

Alternatively, a semi-flexible PCB may be used, also referred to as “semi-flex PCB”, which is composed of a set of plates, typically made of epoxy resin, with film extensions for example made of polyimide.

The presence of the flexible portions makes these printed circuit boards more complex to manufacture, therefore more expensive, and also more fragile. Furthermore, in a space environment, heat is mainly carried away by epoxy plates which are placed in contact with a mechanical support allowing heat to be carried away. Heat dissipation in a semi-flexible printed circuit board is more complex to control, because the heat dissipation capabilities of the substrate films are much more limited than the heat dissipation offered by epoxy plates. This is all the more true in the space domain, where cooling an electronic component by convection is not a workable solution. Consequently, even for semi-flex PCBs, heat is only carried away satisfactorily at the epoxy plates. In addition, the number of layers of a PCB arranged on a film is limited, which limits the number of signals and the current density allowed by these circuits. Signal routing is also more complex due to the impossibility of providing electromagnetic shielding on the substrate films.

### SUMMARY

This disclosure improves the situation.

An electronic device is proposed that is suitable for use on board a spacecraft, comprising at least one motherboard electrically connected to daughterboards, said motherboard and said daughterboards each comprising a support plate in order to form a printed circuit board, each plate extending in a respective main plane, characterized in that each daughterboard comprises at least one first electrical connector fixed to its plate and the motherboard comprises a corresponding number of second connectors fixed to the plate of the motherboard, each first connector engaging with one of the second connectors, said first connector of each daughterboard being arranged on a portion of the plate forming a tab capable of deflection relative to the main plane of the printed circuit board, the tab further comprising cavities for increasing the flexibility of the tab.

In some embodiments, in each daughterboard, the tab is delimited on either side of its first connector by two slots extending transversely from an edge of its plate.

In some embodiments, each tab has at its end a solid portion supporting said first connector.

In some embodiments, said plate is made of epoxy resin, the main plane of the printed circuit board of the motherboard being arranged perpendicularly to the main planes of the printed circuit boards of the daughterboards.

In some embodiments, each first connector comprises guide members arranged at its two ends, providing guidance relative to one of the second connectors.

In some embodiments, each daughterboard is inserted into a metal housing, the metal housings being assembled together and fixed to a supporting structure of the spacecraft, this supporting structure being temperature-regulated by a temperature regulation system.

In some embodiments, each daughterboard is thermally connected to its metal housing via a thermal interface.

In some embodiments, the motherboard is inserted into a metal cover, being thermally connected to the cover by a thermal interface.

Another object of the invention is a spacecraft comprising an electronic device according to the above description.

Another object relates to a method for assembling an electronic device according to the above description, comprising:
a step of assembling daughterboards in their respective housings,
a step of mechanically assembling together the housings of the daughterboards, and
a step of electrically connecting each daughterboard to said motherboard, this step comprising a deflection of a tab of at least one of the daughterboards, said tab supporting a first connector which can engage with second connectors of said motherboard, in order to adapt to the relative positions of the daughterboards and of said motherboard, said first electrical connector being fixed to a support plate of the printed circuit board of said daughterboard, said second connectors being fixed to a support plate of the printed circuit board of said motherboard, said tab of said daughterboard being created by a portion of its plate capable of deflection relative to a main plane of its printed circuit board, and
a step of assembling a cover to the motherboard.

In some embodiments, the assembly method further comprises assembling the housings of the daughterboards to a temperature-regulated supporting structure of the spacecraft.

Advantageously, the designing of electronic assemblies each comprising at least one motherboard and a plurality of daughterboards is facilitated.

Another advantage lies in the improvement of thermal regulation in the areas neighboring the connections between motherboard and daughterboards.

Another advantage is that the proposed electronic device makes it possible to use printed circuit boards arranged on epoxy plates with no flexible parts, which offers advantages in terms of costs and supply. The invention intelligently takes advantage of the slight elasticity of epoxy plates to allow compensating for dimensional tolerance variations during assembly.

Also advantageously, the flexibility of the tab supporting the connector of the daughterboard can be increased by cavities, which also allows reducing the force exerted on each connector. The end of the tab, in front of the cavities, may also remain solid to further reduce the forces exerted on the connector pins.

Also advantageously, the compensation for dimensional tolerance variations made possible by the invention is not achieved at the cost of increasing the overall weight.

### BRIEF DESCRIPTION OF DRAWINGS

Other features, details, and advantages will become apparent upon reading the detailed description below, and upon analyzing the attached drawings, in which:

FIG. 1 shows part of a daughterboard according to the invention.

FIG. 2 represents a connection between a motherboard and a daughterboard according to the invention.

FIG. 3 represents the connection of the invention represented in FIG. 2, in another view.

FIG. 4 represents a motherboard comprising a plurality of connectors according to the invention.

FIG. 5 schematically represents a connection according to the invention between a motherboard and a plurality of daughterboards.

FIG. 6a represents an example of a metal support housing for a daughterboard.

FIG. 6b represents the kinematics of inserting a daughterboard into its housing.

FIG. 7 schematically represents a spacecraft comprising a temperature-regulated supporting structure.

FIG. 8 represents an assembly of a motherboard with a plurality of daughterboards, the daughterboards being contained in respective support housings.

FIG. 9a represents a motherboard assembled with a plurality of daughterboards contained in respective support housings.

FIG. 9b represents the assembly of FIG. 9a after a cover has been assembled over the motherboard.

### DESCRIPTION OF EMBODIMENTS

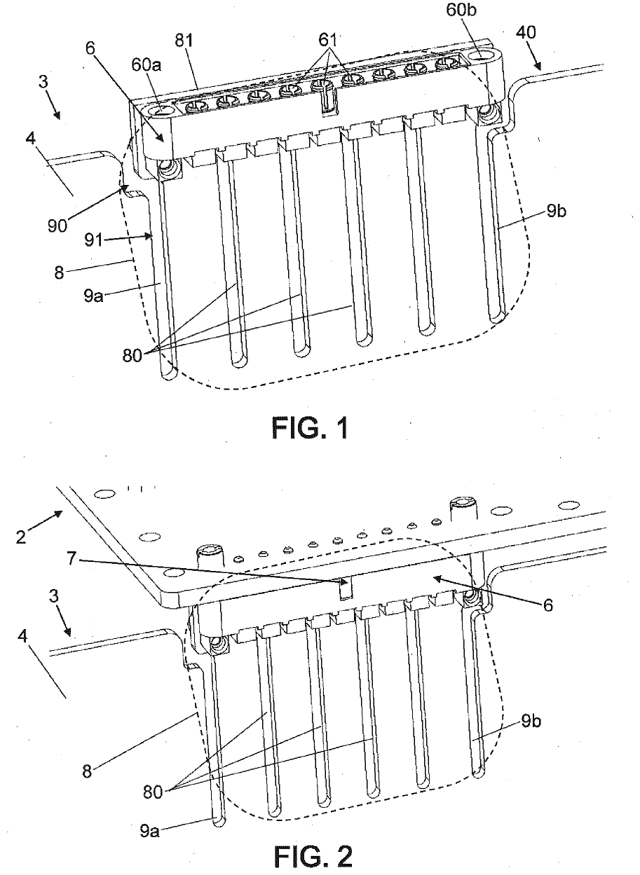

With reference to FIGS. 1 to 5, we will now describe an electronic device 1 suitable for use on board a spacecraft, comprising at least one motherboard 2 and a plurality of daughterboards 3 electrically connected to the motherboard.

Each of motherboard 2 and daughterboards 3 is a circuit board comprising a substantially flat support plate 4, 5. Each support plate 4, 5 can form the substrate of a rigid type of printed circuit board or PCB, and may be formed of an electrically insulating material, for example epoxy resin. A FR4 or polyimide type of PCB may be used, for example. On each plate a set of electrically conductive tracks (not shown) can be arranged, as well as component placements and connectors (not shown) allowing electronic components to be mounted on each card and interconnected. In the invention, the PCBs of daughterboards will be deformed while remaining within manufacturer tolerances so as to preserve the reliability of the PCB.

In addition, each daughterboard 3 comprises a connector 6 fixed to its plate 4, and the motherboard comprises a plurality of connectors, referenced 7a, 7b, 7c and 7d, fixed to plate 5 of the motherboard, each motherboard connector 7 being adapted to engage mechanically and electrically with the connector referenced 6a, 6b, 6c or 6d of a respective daughterboard referenced 3a, 3b, 3c or 3d, in order to connect each daughterboard to the motherboard. Each connector 6, 7 may be fixed to its respective plate, for example by screwing.

Each connector 6, 7 may comprise mechanical guide members 60, 70 and electrical contacts 61, 71. In some embodiments, the connectors extend along a main direction, the mechanical guide members and the electrical contacts being aligned along this main direction. Each connector may comprise two mechanical guide members 60a, 60b, 70a, 70b, one at each end along this main direction, electrical contacts 61, 71 being arranged between the mechanical guide members. This is the case in the example shown in the figures, where the connectors of the daughterboards comprise female guide members capable of receiving complementary male guide members of the motherboard connectors. Of course, this example is in no way limiting, and the opposite case can also be considered. There could also be connectors without mechanical guides.

With reference to FIG. 4, identical connectors 7a, 7b, 7c and 7d of the motherboard are dedicated to the connection with connectors of the respective daughterboards 3a, 3b, 3c and 3d. Each connector of each daughterboard is, for example, identical. The advantageously identical connectors of the motherboard are mounted on the same face of support plate 5 of the motherboard. Furthermore, these connectors 7a, 7b, 7c and 7d are aligned parallel to each other so as to be able to connect several daughterboards to the motherboard such that the daughterboards extend parallel to each other.

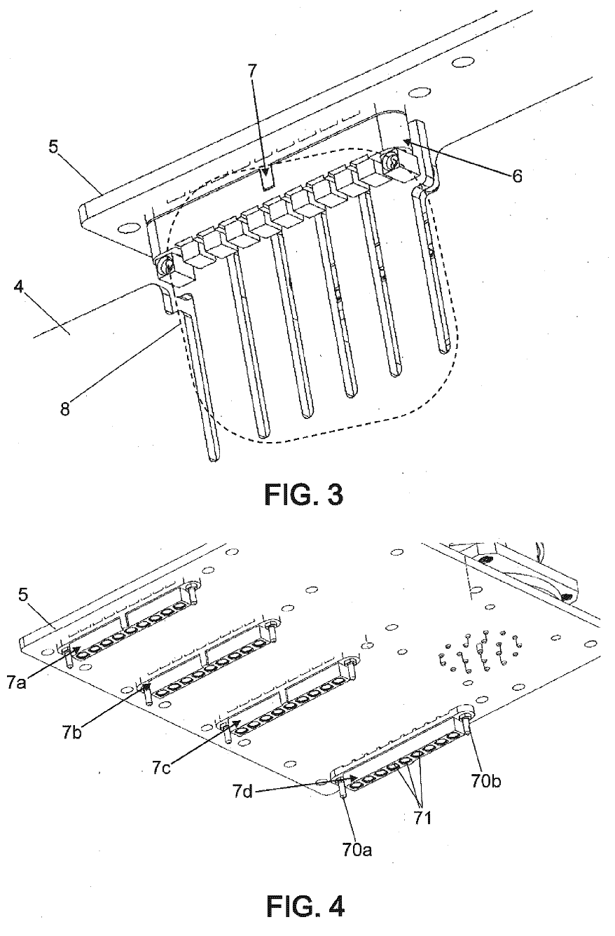

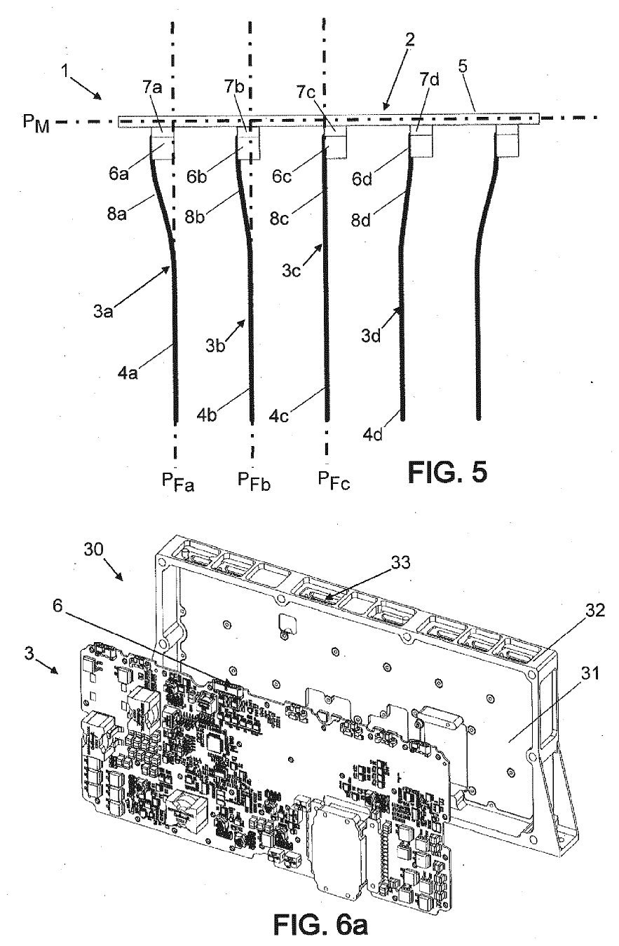

As shown in FIGS. 3 and 5, connectors 6, 7 of the motherboard and the daughterboards are shaped to allow a connection between the motherboard and the daughterboards such that the plane PM of support plate 5 of motherboard 2 is perpendicular to the planes PFa, PFb, PFc of support plates 4a, 4b, 4c of daughterboards 3a, 3b, 3c. FIG. 5 shows each tab, and in its extension, the main plane of each daughterboard. The connectors thus create a connection perpendicular to the motherboard, then two deviations in opposite directions to join the main plane, also perpendicular to the motherboard. In this regard, the connectors of the motherboard or daughterboards may be right-angled connectors, i.e. in which the connection pins extend parallel to the plate on which the connector is mounted, while the other connectors are straight connectors, i.e. their connection pins extend perpendicularly to the plate on which the connector is mounted.

In order to be able to connect several daughterboards 3 to motherboard 2 while overcoming the issues related to dimensional tolerance variations in the components, the positioning of the components, or even the flatness of the PCBs, plate 4 of each daughterboard 3 comprises a portion forming a tab 8 capable of deflection relative to the main plane of support plate 4 of the board, this portion supporting connector 6 of the daughterboard. With reference to FIG. 1, tab 8 may be delimited on either side of the connector by two slots 9a, 9b extending transversely from an edge 40 of the plate, connector 6 itself being mounted on the plate between the slots, and preferably at or near this edge. In this manner, with reference to FIG. 5, it is possible to compensate for certain tolerance variations or misalignments by giving a slight elasticity to this portion of the plate, making it possible to bend tab 8 on which connector 6 is mounted. Thus, and as shown schematically in FIG. 5, at the time of assembly of the electronic device, comprising the connecting of several daughterboards 3a to 3d to motherboard 2, it is possible to position each daughterboard relative to the motherboard, and to deflect tab 8a to 8d carrying connector 6a to 6d of each daughterboard 3a to 3d in order to connect it to a respective connector 7a to 7d of a motherboard.

The two slots 9a, 9b laterally delimiting tab 8 are advantageously dimensioned according to the desired deflection of tab 8 relative to the plane of the plate. They can for example have a length of between 1 and 5 cm, this length being measured from the edge of the plate to the end of each slot. According to one non-limiting example, the two slots can have a length of 3 cm to compensate for an offset of 400 μm between an electrical connector carried by the motherboard and the corresponding connector of the daughterboard.

In some embodiments, tab 8, meaning the portion of the board between side slots 9a, 9, may be longer than the portions of the plate located externally to the slots, so as to have a tab that protrudes relative to the edge of the plate, which can allow greater ease in the assembly and manipulation of the connectors.

The two slots 9a, 9b extending on either side of the connector may extend perpendicularly to edge 40 of plate 4. In one embodiment, the two slots 9 may comprise a first angled portion 90 extending from the edge of the plate and around the lateral ends of the connector, and a straight end portion 91 extending for example perpendicularly to the edge of the plate. In this manner, the tab has a width, between the lateral ends of the two slots, which is less than the width of the connector, which gives greater flexibility to the tab. The average width of the tab may in particular be reduced due to the two shoulders 90 at the edge of the daughterboard. The base of the tab then has a first width extending to a widened portion of the tab on which its connector is fixed. In the non-limiting example shown in FIG. 1, the connector comprises two guide members 60a, 60b one at each end, and each slot comprises an end portion 91 aligned with each guide member of the connector and an angled portion 90 connecting the end portion to the edge of the plate, thus forming a shoulder.

In some embodiments, tab 8 also comprises one or more cavities 80 to make the tab more flexible, arranged in a middle portion of the tab. These cavities may or may not pierce all the way through.

Each tab 8 comprises for example a plurality of rectilinear cavities 80 extending parallel to each other as grooves pierced all the way through the tab, and, where appropriate, parallel to the slots delimiting the tab. Even so, the tab may comprise a solid portion 81 supporting the connector, at its end located towards the plate edge. In this case, cavities 80 to increase the flexibility of tab 8 may extend from solid portion 81 to the level of the ends of slots 9a and 9b.

The fact that a solid portion 81 is retained in order to support the connector allows reducing the pulling stresses applied to the electrically conductive pins of the connector which are arranged in this solid portion 81.

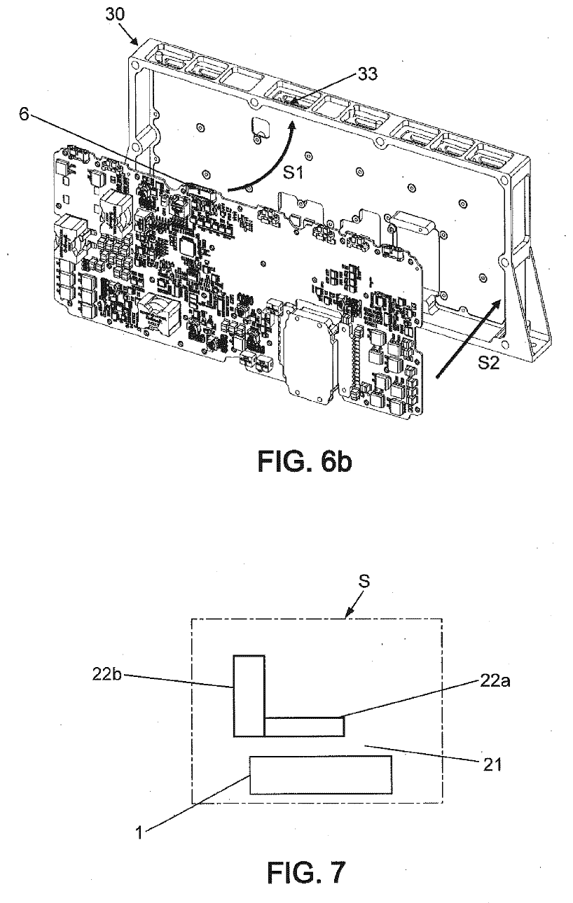

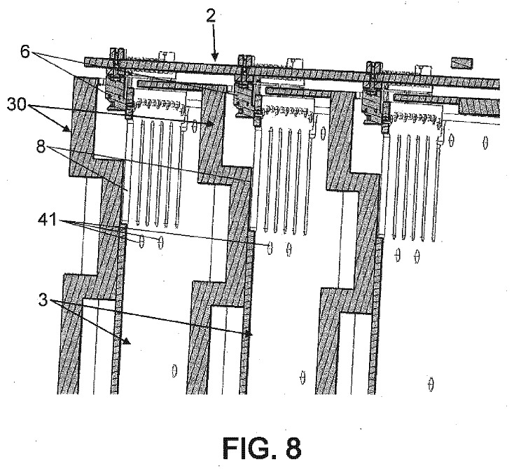

Each daughterboard 3 can be inserted into a respective metal housing 30, each board able to be thermally connected to its respective housing by a thermal interface (not shown). With reference to FIG. 6a, a daughterboard and its support housing 30, also called a seating, are shown. Housing 30 of each daughterboard is shaped to allow deflection of the tab. In particular, tab 8 is not fixed to the housing by a thermal interface. The heat generated on the board is carried away through the PCB into the metal frame. In FIG. 6b, the kinematics of insertion of daughterboard 3 into housing 30 are shown. The housing may in particular comprise a bottom wall 31 and a peripheral rim 32 delimiting an open cavity in which the board can be inserted. Housing 30 comprises a through-hole 33 arranged in peripheral rim 32 and dimensioned to allow insertion of connector 6 carried by tab 8 of a daughterboard, through the hole. In a first step S1, the daughterboard is therefore inserted into the housing in an inclined position relative to the plane of the bottom wall of the housing, while inserting the connector carried by tab 8 through hole 33, then it is lowered S2 from the incline to extend parallel to the plane of the bottom wall of the housing. It can then be mechanically assembled to housing 30, for example by screwing. With reference to FIG. 8, plate 4 of a daughterboard may comprise bores 41 enabling the daughterboard to be screwed to the bottom wall of the housing. Thus, each daughterboard is rigidly assembled to its housing but tab 8 remains movable relative to the plane of each plate, being free to deflect slightly through through-hole 33 of each housing. This allows the daughterboards to be assembled to the motherboard by slightly deflecting the tab carrying the connector of one or more daughterboards so as to match the alignment of the motherboard's connectors. Thus, incorrect positioning of the daughterboard connectors in relation to the motherboard connector can be compensated for.

Once each daughterboard is assembled in its housing, the housings are rigidly assembled together.

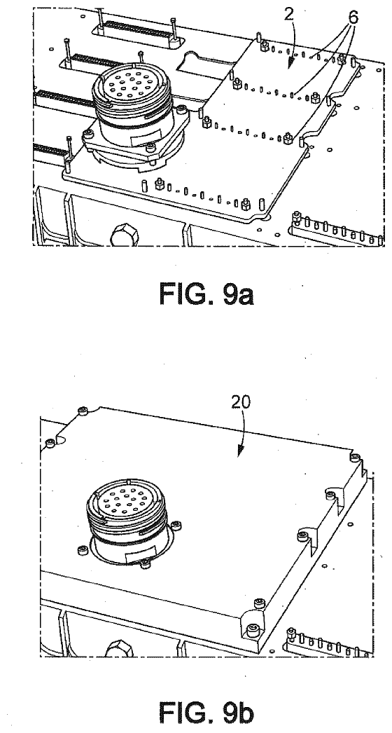

With reference to FIGS. 8 and 9a, the motherboard is then assembled to the daughterboards, by connecting each connector of the motherboard to a respective connector of a daughterboard, said connector being deflected if necessary.

With reference to FIG. 9b, motherboard 2 is assembled with a cover 20 which may be in the form of a bottom wall provided with a peripheral rim and thus forming an open cavity, this open cavity being oriented towards the daughterboards when assembling the motherboard to the daughterboards.

With reference to FIG. 7, when the electronic device 1 is on board a spacecraft S, each housing 30 of a daughterboard may itself be fixed to a supporting structure 21 of the spacecraft which may be temperature-regulated by a thermal regulation system, comprising for example a heat transfer structure comprising an evaporator 22a connected to a heat source, in this case electronic device 1 through the supporting structure 21, and a radiator 22b located outside the spacecraft S so as to release the heat into space.

Thus, according to one embodiment, a method for assembling an electronic device according to the above description may further comprise the attachment of the housings of the daughterboards and/or of the cover of the motherboard to the supporting structure 21 of the spacecraft, this supporting structure being temperature-regulated by a temperature regulation system 22.

1. A electronic device configured for use on board a spacecraft, the electronic device comprising:
at least one motherboard electrically connected to daughterboards, said at least one motherboard and said daughterboards, wherein each of the daughterboards comprises a respective support plate which forms a printed circuit board for the daughterboard,
each support plate extends in a respective main plane,
each of the daughter boards comprise at least one first electrical connector fixed to the support plate for the daughterboard, and
the motherboard comprises second connectors fixed to a support plate of the motherboard,
each of the first connectors engages a respective one of the second connectors, and
each of said first connectors of the daughterboards is arranged on a portion of a tab of the support plate for the daughterboard, wherein each of the tabs is configured to deflect relative to the main plane of the support board of the corresponding daughter board,
wherein each of the tabs further comprises cavities configured to increase tab flexibility.

2. The electronic device according to claim 1, wherein, for each of the daughter boards, the tab is delimited on either side of the first connector by two slots extending transversely from an edge of the support plate for the daughterboard.

3. The electronic device according to claim 1, wherein each of the tabs has at an end of the tab a solid portion supporting said first connector.

4. The electronic device according to claim 1, wherein said support plates are made of epoxy resin, and
a main plane of the support board of the motherboard is perpendicular to the main planes of the support boards of the daughterboards.

5. The electronic device according to claim 1, wherein each of the first connectors comprises guide members arranged at ends of the first connectors, and
the guide members are configured to provide guidance relative to a respective one of the second connectors.

6. The electronic device according to claim 1, wherein each of the daughter boards is inserted into a metal housing,
wherein the metal housings are assembled together and fixed to a supporting structure of the spacecraft, and the supporting structure is temperature-regulated by a temperature regulation system.

7. The electronic device according to claim 6, wherein each of the daughterboards is thermally connected to the metal housing of the daughterboard via a thermal interface.

8. The electronic device according to claim 1, wherein the motherboard is inserted into a metal cover and the mother board is thermally connected to the metal cover by a thermal interface.

9. A spacecraft comprising the electronic device according to claim 1.

10. A method for assembling the electronic device according to claim 1, comprising:
assembling daughterboards in respective housings,
mechanically assembling together the housings of the daughterboards,
electrically connecting each of the daughter boards to said motherboard, including deflection of the tab of at least one of the daughterboards, said tab supporting the first connector which engages one of the second connectors of said motherboard, in order to adapt to a relative positions of the daughterboards and of said motherboard, said first electrical connector being fixed to a support plate of the printed circuit board of said daughterboard, said second connectors being fixed to a support plate of the support board of said motherboard, said tab of said daughterboard being created by a portion of its plate capable of deflection relative to a main plane of its printed circuit board, and
assembling a cover to the motherboard.

11. The method for assembling an electronic device according to claim 10, further comprising assembling of the housings of the daughterboards to a temperature-regulated supporting structure of the spacecraft.

12. A electronic device configured for use on board a spacecraft, the electronic device comprising:
a motherboard including a motherboard support board including a printed circuit board;
daughterboards each including a daughterboard support board including a printed circuit, wherein each of the daughterboard support boards are parallel to each other;
each of the daughterboards includes a respective first electrical connector fixed to the support plate for the daughterboard,
the motherboard comprises second connectors fixed to the motherboard support plate, and the first electrical connectors of the daughterboards are configured to engage a corresponding one of the second connectors;
each of the first connectors of the daughterboards are arranged on a portion of a tab of the support plate for the daughterboard, wherein each of the tabs are configured to deflect out of a plane of the support board for the daughterboard,
wherein each of the tabs includes a cavity configured to increase tab flexibility of the tab.

13. The electronic device according to claim 12, wherein in each daughterboard, the tab is delimited on opposite sides of the first connector corresponding to the tab by slots transverse to an edge of the support plate for the daughterboard.

14. The electronic device according to claim 12, wherein each of the tabs has at an end of the tab a solid portion supporting the first connector associated with the tab.

15. The electronic device according to claim 12, wherein said support plates of the daughterboards are formed of an epoxy resin, and
a main plane of the support board of the motherboard is perpendicular to the main planes of the support boards of the daughterboards.

16. The electronic device according to claim 12, wherein each of the first connectors comprises guide members arranged at ends of the first connectors, and
the guide members are configured to provide guidance relative to a respective one of the second connectors.

17. The electronic device according to claim 12, wherein each of the daughter boards housed in a metal housing, and the metal housings form an assembly fixed to a supporting structure of the spacecraft, and
the supporting structure is temperature-regulated by a temperature regulation system.

18. The device according to the claim 17, wherein each of the daughterboards is thermally connected to the metal housing of the daughterboard via a thermal interface.

19. The electronic device according to claim 1, wherein the motherboard is inserted into a metal cover and the mother board is thermally connected to the metal cover by a thermal interface.
